(19) United States
(12) Patent Application Publication
(10) Pub. No.: US 2024/0402217 A1
(43) Pub. Date: Dec. 5, 2024

(54) SYSTEMS AND METHODS FOR COAXIAL TEST SOCKET AND PRINTED CIRCUIT BOARD INTERFACES

(71) Applicants: Smiths Interconnect Americas, Inc., Kansas City, KS (US); ANTARES ADVANCED TEST TECHNOLOGIES (SUZHOU) LIMITED, Jiangsu (CN)

(72) Inventors: Khaled Elmadbouly, Gilbert, AZ (US); Rock Yan, Suzhou, Jiangsu (CN); Jiachun Zhou, Fremont, CA (US); Dexian Liu, Suzhou, Jiangsu (CN); Annie Mu, Suzhou, Jiangsu (CN)

(21) Appl. No.: 18/695,994

(22) PCT Filed: Sep. 26, 2022
(86) PCT No.: PCT/US2022/044675

§ 371 Date: Mar. 27, 2024

(30) Foreign Application Priority Data
Sep. 27, 2021 (CN) 202111135634.4

(51) Int. Cl. G01R 1/04; G01R 1/067; G01R 31/28

(52) U.S. Cl. CPC G01R 1/0466; G01R 1/06716; G01R 1/0675; G01R 31/2808; G01R 31/2863; G01R 31/2889

(57) ABSTRACT

A test socket for coupling an integrated circuit (IC) chip to a printed circuit board (PCB) is provided. The test socket includes a conductive body having a first surface configured to face the PCB and a second surface configured to face the IC chip. The conductive body defines a signal cavity and a ground cavity extending from the first surface to the second surface. The test socket further includes a signal probe disposed in the signal cavity. The signal probe is configured to electrically connect to a signal conductor of the PCB and to a signal pad of the IC chip. The test socket further includes a ground probe disposed in the ground cavity. The ground probe is configured to electrically connect to a ground conductor of the PCB and to a ground pad of the IC chip. The ground probe is further electrically connected to the conductive body.

### BACKGROUND

The embodiments described herein relate generally to electrical interconnects and, more particularly, to interfaces for coaxial test sockets and printed circuit boards (PCBs).

In the electronics and semiconductor industries, systems used to test integrated circuit (IC) semiconductor chips often include test sockets. A test socket is disposed on a PCB, or “load board,” and may include a socket body and one or more probes (i.e., electrical contacts or pins) that electrically connect the IC chip to the PCB. Test sockets generally must meet various electrical and mechanical performance thresholds to adequately test a given IC chip. For example, the test socket should maintain signal integrity, such as a desired error rate or signal-to-noise ratio, at a desired data transfer rate for the IC under test. Current test sockets generally maintain signal integrity up to a data transfer rate of about 30 gigabits per second. Some applications, such as 5G telecommunications or artificial intelligence, may require higher rates of data transfer. A test socket capable of maintaining signal integrity at higher data transfer rates is therefore desirable.

### BRIEF SUMMARY

In one aspect, a test socket for coupling an integrated circuit (IC) chip to a printed circuit board (PCB) is provided. The test socket includes a conductive body having a first surface configured to face the PCB and a second surface configured to face the IC chip. The conductive body defines a signal cavity and a ground cavity. The signal cavity and the ground cavity extend from the first surface to the second surface. The test socket further includes a signal probe disposed in the signal cavity. The signal probe is configured to electrically connect to a signal conductor of the PCB and to a signal pad of the IC chip. The test socket further includes a ground probe disposed in the ground cavity. The ground probe is configured to electrically connect to a ground conductor of the PCB and to a ground pad of the IC chip. The ground probe is further electrically connected to the conductive body.

In another aspect, a method for manufacturing a test socket is provided. The method includes forming a conductive body having a first surface configured to face a PCB and a second surface configured to face an IC chip. The conductive body defines a signal cavity and a ground cavity. The signal cavity and the ground cavity extend from the first surface to the second surface. The method further includes positioning a signal probe in the signal cavity. The signal probe is configured to electrically connect to a signal conductor of the PCB and to a signal pad of the IC chip. The method further includes positioning a ground probe in the ground cavity. The ground probe is configured to electrically connect to a ground conductor of the PCB and to a ground pad of the IC chip. The ground probe is further electrically connected to the conductive body.

In another aspect, an IC chip testing assembly is provided. The IC chip testing assembly includes comprising a PCB including a signal conductor and a ground conductor, an IC chip comprising a signal pad and a ground pad, and a test socket. The test socket includes a conductive body having a first surface configured to face the PCB and a second surface configured to face the IC chip. The conductive body defines a signal cavity and a ground cavity. The signal cavity and the ground cavity extend from the first surface to the second surface. The test socket further includes a signal probe disposed in the signal cavity. The signal probe is configured to electrically connect to the signal conductor and to said signal pad. The test socket further includes a ground probe disposed in the ground cavity. The ground probe is configured to electrically connect to the ground conductor and to said ground pad. The ground probe is further electrically connected to the conductive body.

### BRIEF DESCRIPTION OF THE DRAWINGS

FIGS. 1-10 show example embodiments of the systems and methods described herein.

FIG. 1 is a cross-sectional view of an example test assembly including an example test socket;

FIG. 2 is a cross-sectional view of another example test assembly wherein the test socket includes an insulation layer;

FIG. 3 is a cross-sectional view of another example test assembly wherein the test socket includes conductive contacts;

FIG. 4 is a cross-sectional view of another example test assembly wherein the test socket includes conductive members;

FIG. 5 is a cross-sectional view of another example test assembly wherein the test socket includes half counterbores;

FIG. 6 is a cross-sectional view of another example test assembly wherein the test socket includes no counterbores;

FIG. 7 is a partially transparent view of an example test socket including conductive shield needles;

FIG. 8 is a partially transparent view of an example test assembly wherein an air gap is present between the test socket and the PCB;

FIG. 9 is a cross-sectional view of an example test assembly wherein an air gap surrounds a power probe of the test socket; and

FIG. 10 is a flowchart of an exemplary method for manufacturing the test socket shown in FIG. 1.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, is applied to modify any quantitative representation that could permissibly vary without resulting in a change in the basic function to which it is related. Accordingly, a value modified by a term or terms, such as “about”, “approximately”, and “substantially”, is not to be limited to the precise value specified. In at least some instances, the approximating language may correspond to the precision of an instrument for measuring the value. Here and throughout the specification and claims, range limitations are combined and interchanged, such ranges are identified and include all the sub-ranges contained therein unless context or language indicates otherwise.

The disclosed systems and methods include a test socket for coupling an integrated circuit (IC) chip to a printed circuit board (PCB), for example, to facilitate testing of the IC chip using the PCB. The test socket includes a conductive body having a first surface facing the PCB and a second surface facing the IC chip. The conductive body defines one or more signal cavities and one or more ground cavities, each extending from the first surface to the second surface. The test socket further includes one or more signal probes each disposed in one of the signal cavities. The signal probes are configured to electrically connect to a signal conductor of the PCB and to a signal pad of the IC chip, for example, to enable a transmission of electrical signals between the PCB and the IC chip. The test socket further includes one or more ground probes each disposed in one of the ground cavities. The ground probes are configured to electrically connect to a ground conductor of the PCB and to a ground pad of the IC chip to enable an electrical connection of respective grounds of the PCB and IC chip. The ground probe is further electrically connected to the conductive body. The conductive body may also define one or more power cavities extending from the first surface to the second surface, and in which a power probe may be disposed. Likewise, the power probe is configured to electrically connect to a power conductor of the PCB and to a power pad of the IC chip. The ground probe is configured to be electrically connected to the conductive body, enabling the conductive body to function as a coaxial shielding for the signal probe and enabling the test socket to achieve improved electrical performance on parameters such as, for example, a higher data transfer rate. In certain embodiments, the signal pad, ground pad, and power pad of the IC chip are solder balls.

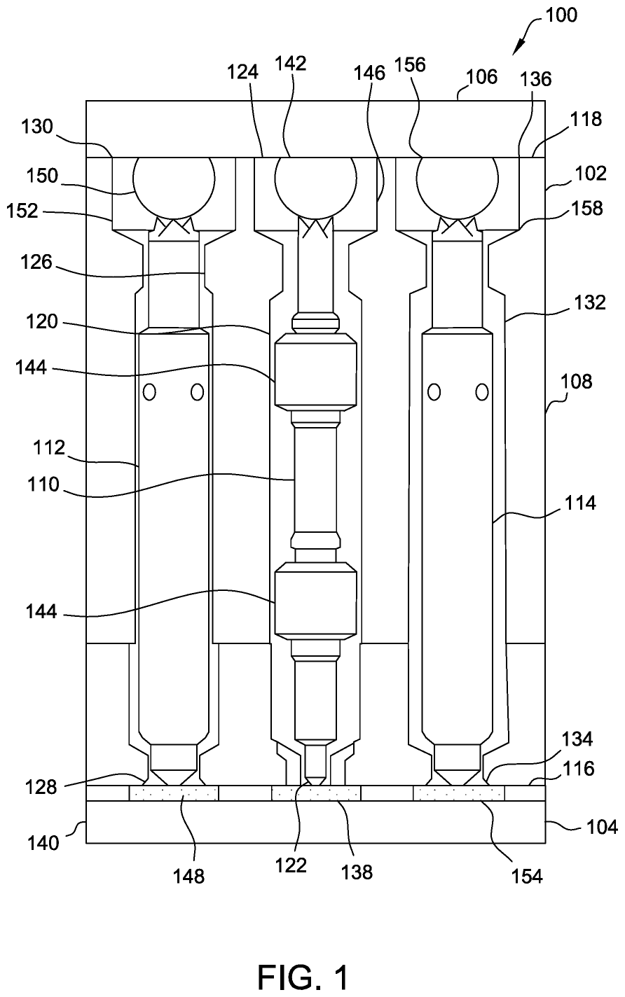

FIG. 1 is a cross-sectional view of an example test assembly 100 including a test socket 102, a PCB 104, and an integrated circuit (IC) chip 106. In some embodiments, test socket 102 is configured to enable a communicative coupling of IC chip 106 chip to PCB 104 for testing IC chip 106. As described in further detail below, test socket 102 provides for the transmission of electrical signals and electrical power between PCB 104 and IC chip 106 and a connection of respective electrical grounds of PCB 104 and IC chip 106.

Test socket 102 includes a conductive body 108, a signal probe 110, a ground probe 112, and a power probe 114. Conductive body 108 has a first surface 116 disposed adjacent to PCB 104 and a second surface 118 disposed adjacent to IC chip 106. Conductive body 108 is electrically conductive, and includes a conductive material such as, for example, aluminum, magnesium, titanium, zirconium, copper, iron, or an alloy including one or more thereof. Conductive body 108 includes a plurality of cavities, including a signal cavity 120 extending from a first signal opening 122 at first surface 116 to a second signal opening 124 at second surface 118, a ground cavity 126 extending from a first ground opening 128 at first surface 116 to a second ground opening 130 at second surface 118, and a power cavity 132 extending from a first power opening 134 at first surface 116 to a second power opening at 136 at second surface 118. In some embodiments, conductive body 108 includes a plurality of signal cavities 120, ground cavities 126, and/or power cavities 132. In certain embodiments, a distance between any two of signal probe 110, ground probe 112, and power probe 114 is greater than about 50 millimeters center to center.

Signal probe 110 is located within signal cavity 120, and is configured to contact and electrically connect to a signal conductor 138 disposed on a substrate 140 of PCB 104 and to a signal pad 142 of IC chip 106 to enable a transmission of electrical signals between PCB 104 and IC chip 106. Signal probe 110 may include a single conductive piece or may include multiple components. For example, in some embodiments, signal probe 110 is a spring probe. Signal probe 110 is electrically insulated from conductive body 108. For example, in certain embodiments, signal probe 110 or signal cavity 120 may include an electrically insulative coating (not shown). In such embodiments, the insulative coating may be, for example, an anodic film generated on the metal, a polytetrafluoroethylene (PTFE) coating, a combination thereof, or another coating or sealing material. For example, in some such embodiments, the coating includes an anodized aluminum layer having a thickness of greater than about 0.02 millimeters and a PTFE sealing layer having a thickness of greater than about 0.001 millimeters. In some embodiments, signal probe 110 includes one or more insulation members 144 disposed on signal probe 110. While two insulation members 144 are shown, there may be more or less than two insulation members 144 on signal probe 110. Insulation members 144 may be rings that wrap around a portion of a circumference of the outside surface of signal probe 110 or may wrap around the entirety of a circumference of the outside surface of signal probe 110. Accordingly, insulation members 144 may be annular in shape. In some embodiments signal cavity 120 widens at second signal opening 124 to form a signal counterbore 146. In such embodiments, signal counterbore 146 is shaped to receive at least a portion of signal pad 142 without causing signal pad 142 to contact conductive body 108.

Signal probe 110 and signal cavity 120 together form a coaxial transmission line. Accordingly, signal probe 110, signal cavity 120, insulation members 144, and signal counterbore 146 may be shaped and sized to achieve desired electrical properties such as, for example, achieving a constant impedance, reducing reflection or distortion of electrical signals, reducing insertion loss and return loss, achieving a desired characteristic impedance, and/or reducing crosstalk.

Ground probe 112 is located within ground cavity 126, and is configured to contact and electrically connect to a ground conductor 148 of PCB 104 and a ground pad 150 of IC chip 106 to electrically connect respective grounds of PCB 104 and IC chip 106. Ground probe is further electrically connected to conductive body 108. For example, as shown in FIG. 1, ground probe 112 may contact conductive body 108. Because no insulation separates ground probe 112 and conductive body 108, ground probe 112 and conductive body 108 are electrically connected when placed in contact. As described in further detail below, in some embodiments, test socket 102 includes additional features for improving the electrical connection between ground probe 112 and conductive body 108. Like signal probe 110, ground probe 112 may include a single conductive piece or include multiple components. For example, in some embodiments, ground probe 112 is a spring probe. In some embodiments ground cavity 126 widens at second ground opening 130 to form a ground counterbore 152, which may be similar in structure to signal counterbore 146.

Power probe 114 is located within power cavity 132, and is configured to contact and electrically connect to a power conductor 154 of PCB 104 and a power pad 156 of IC chip 106 to provide power to IC chip 106 from PCB 104. Like signal probe 110 and ground probe 112, power probe 114 may include a single conductive piece or include multiple components. For example, in some embodiments, power probe 114 is a spring probe. Like signal probe 110, power probe 114 is electrically insulated from conductive body 108. For example, in certain embodiments, power probe 114 may include an electrically insulative coating (not shown) and/or insulation members similar to insulation members 144. In some embodiments power cavity 132 widens at second power opening 136 to form a power counterbore 158, which may be similar in structure to signal counterbore 146 and/or ground counterbore 152.

Conductive body 108 is electrically connected to ground conductor 148 of PCB 104 at least through ground probe 112. In some embodiments, conductive body 108 is directly electrically connected to ground conductor 148. For example, conductive body 108 may be configured to contact ground conductor 148 when installed, and/or test socket 102 may include additional components for electrically connecting conductive body 108 to ground conductor 148.

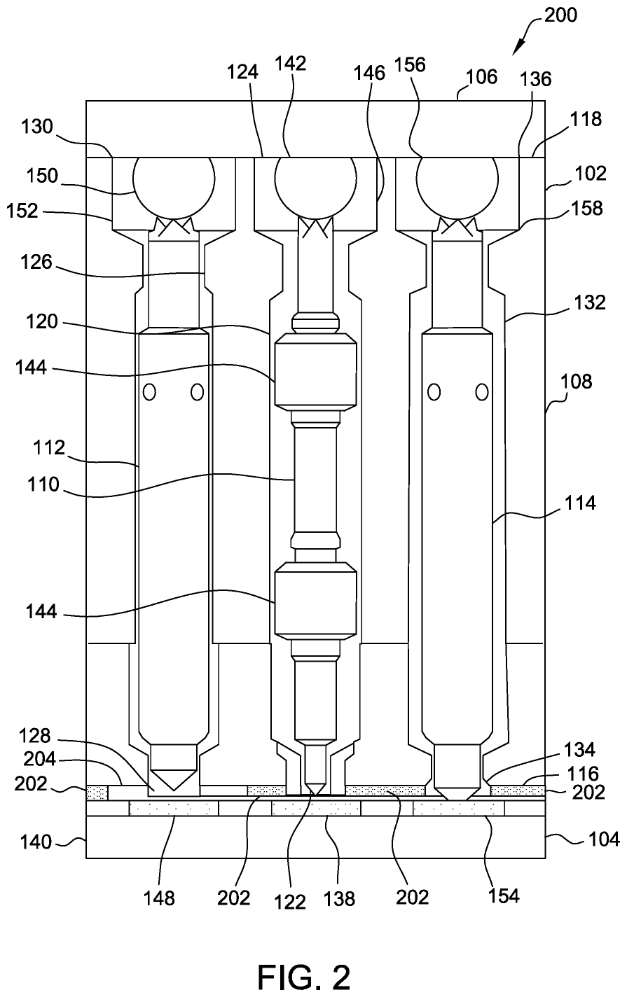

FIG. 2 is a cross-sectional view of another example test assembly 200. Test assembly 200 includes test socket 102, PCB 104, and IC chip 106, which generally function as described with respect to FIG. 1. As shown in FIG. 2, in some embodiments, test socket 102 includes an insulation layer 202 disposed on first surface 116 of conductive body 108. Insulation layer 202 insulates conductive body 108 from conductors of PCB 104. In some such embodiments, conductive body 108 and insulation layer 202 define a recess 204 around first ground opening 128 where no insulation layer 202 is present. In such embodiments, recess 204 enhances the electrical connection between conductive body 108, ground probe 112, and ground conductor 148 to improve the electrical grounding of conductive body 108. A shape and depth of recess 204 may be selected to achieve certain electrical characteristics for test socket 102.

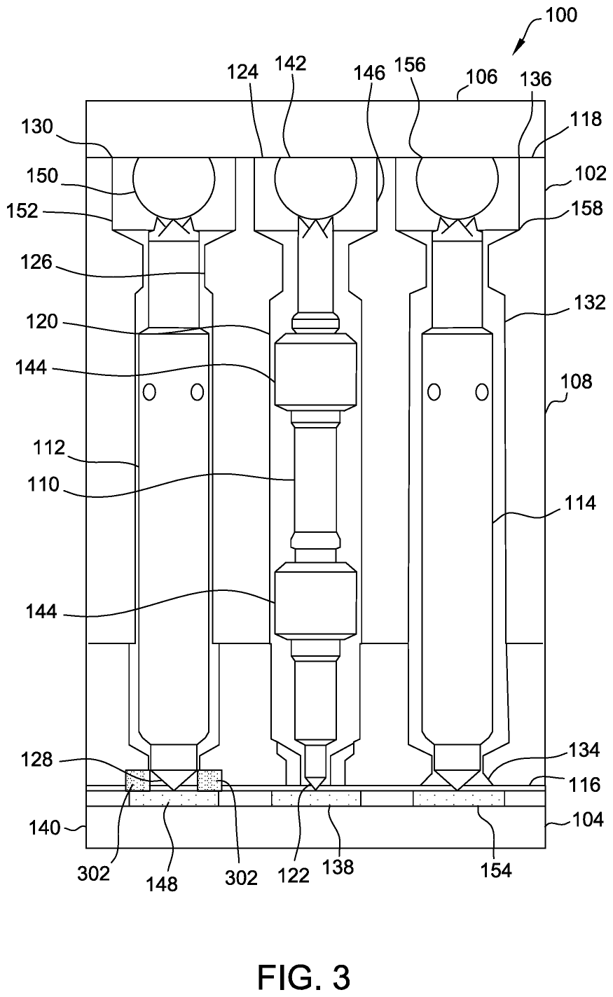

FIG. 3 is a cross sectional view of another example test assembly 300. Test assembly 300 includes test socket 102, PCB 104, and IC chip 106, which generally function as described with respect to FIG. 1. As shown in FIG. 3, in some embodiments, conductive body 108 includes conductive contacts 302 disposed on first surface 116, which are configured to contact ground conductor 148 when test socket 102 is installed. Accordingly, conductive contacts 302 form an electrical connection between conductive body 108 and ground conductor 148. In some embodiments, conductive contacts 302 extend from first surface 116. In certain embodiments, conductive contacts are disposed proximate to ground probe 112, for example, as a ring extending from first surface 116 around an edge of second ground opening 130. In some embodiments, conductive body 108 and conductive contact 302 are at least partially formed from one integrated piece of material. Alternatively, conductive contacts 302 may be separate pieces of material disposed on first surface 116 and in electrical connection with conductive body 108.

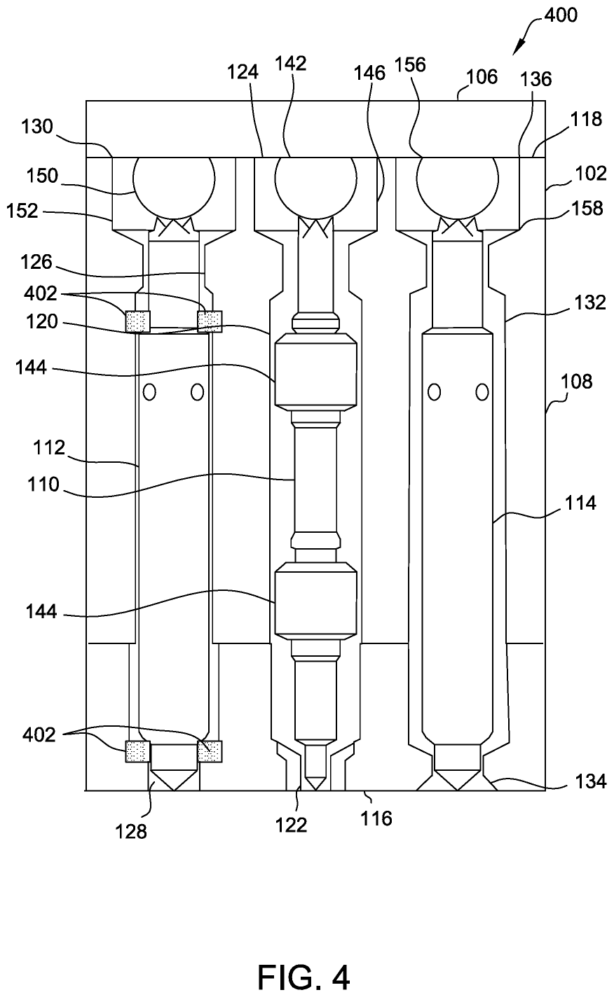

FIG. 4 is a cross sectional view of another example test assembly 400. Test assembly 400 includes test socket 102, PCB 104, and IC chip 106, which generally function as described with respect to FIG. 1. As shown in FIG. 4, in some embodiments, test socket 102 further includes one or more conductive members 402 disposed on ground probe 112. Conductive members 402 contact conductive body 108 and ground probe 110 to provide an electrical connection between conductive body 108 and ground probe 110. In some embodiments, conductive members include and/or are formed from elastomer. While two conductive members 402 are shown, there may be more or less than two conductive members 402 on ground probe 112. Conductive members 402 may be rings that wrap around a portion of a circumference of the outside surface of ground probe 112 or may wrap around the entirety of a circumference of the outside surface of ground probe 112. Accordingly, conductive members 402 may be annular in shape. In certain embodiments, as shown in FIG. 4, test socket 102 includes at least one conductive member 402 proximate to first ground opening 128 and at least one conductive member proximate to second ground opening 130.

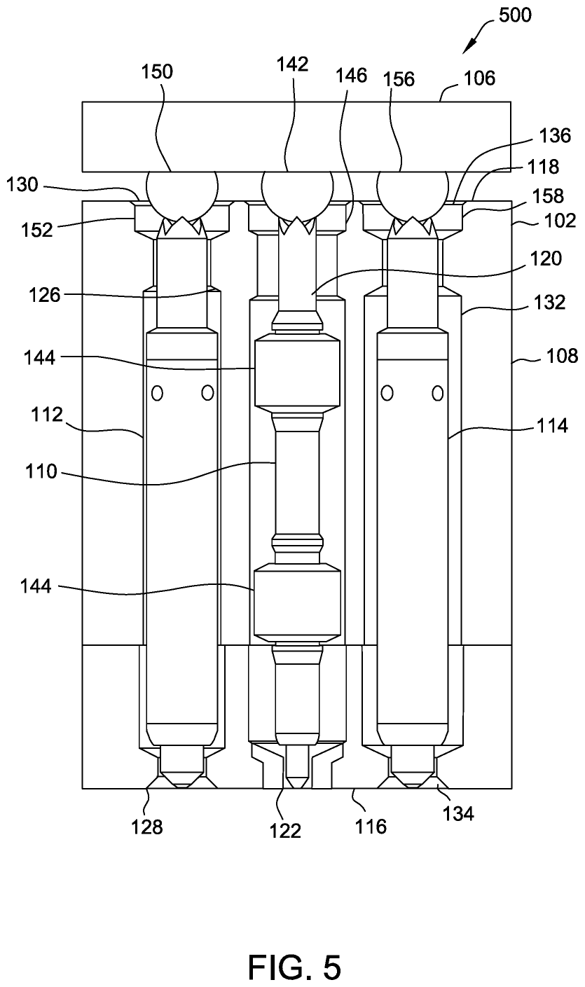

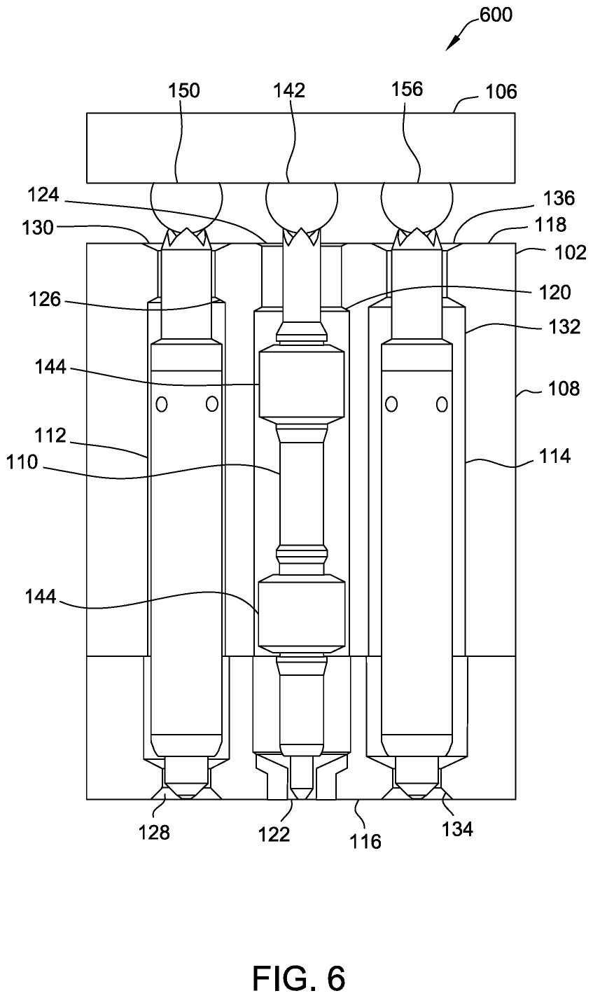

FIG. 5 is a cross sectional view of another example test assembly 500, and FIG. 6 is a cross sectional view of a further test assembly 600. Test assembly 500 and test assembly 600 each include test socket 102 and IC chip 106, which generally function as described with respect to FIG. 1. As shown in FIG. 5, in some embodiments, signal counterbore 146, ground counterbore 152, and power counterbore 158 have a depth less than a height of signal pad 142, ground pad 150, and power pad 156. For example, in some such embodiments, a depth of signal counterbore 146, ground counterbore 152, and power counterbore 158 is about half the height of signal pad 142, ground pad 150, and power pad 156. As shown in FIG. 6, in certain embodiments, conductive body 108 does not include one or more of signal counterbore 146, ground counterbore 152, or power counterbore 158. In some such embodiments, power probe 110, ground probe 112, and/or power probe 114 may extend to or past second surface 118 of conductive body 108. By selecting a depth of signal counterbore 146, ground counterbore 152, or power counterbore 158 as shown in FIGS. 5 and 6, a distance (i.e., a gap) between test socket 102 and IC chip 106 may be selected to achieve certain properties for test socket 102 such as, for example, optimizing fit and required impedance.

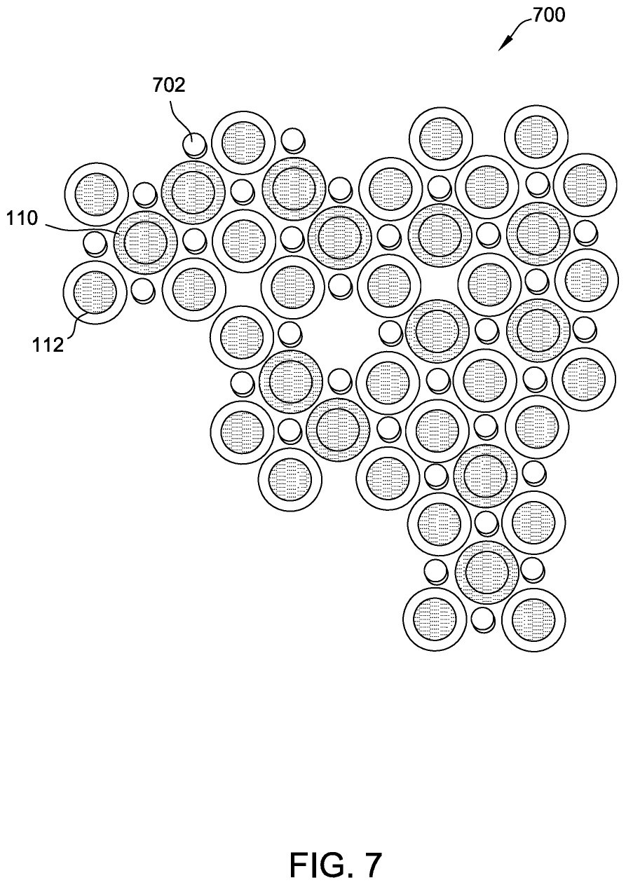

FIG. 7 is a partially transparent perspective view of example test socket 102, showing a plurality of signal probes 110 and ground probes 112, which generally function as described with respect to FIG. 1. As shown in FIG. 7, in some embodiments, test socket 102 further includes a plurality of conductive shield needles 702 extending from one of first surface 116 or second surface 118 and configured to contact one of ground conductor 148 or ground pad 150, respectively. In some such embodiments, conductive shield needles partially surround at least one power probe 110.

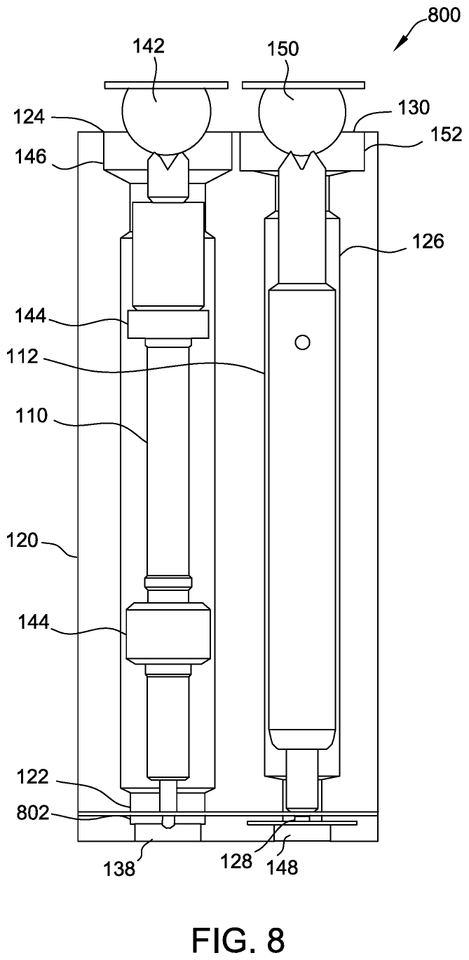

FIG. 8 is another partially transparent view of example test socket 102 showing power probe 110 and ground probe 112. As shown in FIG. 8, in some embodiments a gap 802 is present between conductive body 108 and power conductor 154. A width of gap 802 may be selected to achieve certain electrical characteristics for test socket 102. In certain embodiments, gap 802 is between about 0.02 and 0.1 millimeters wide.

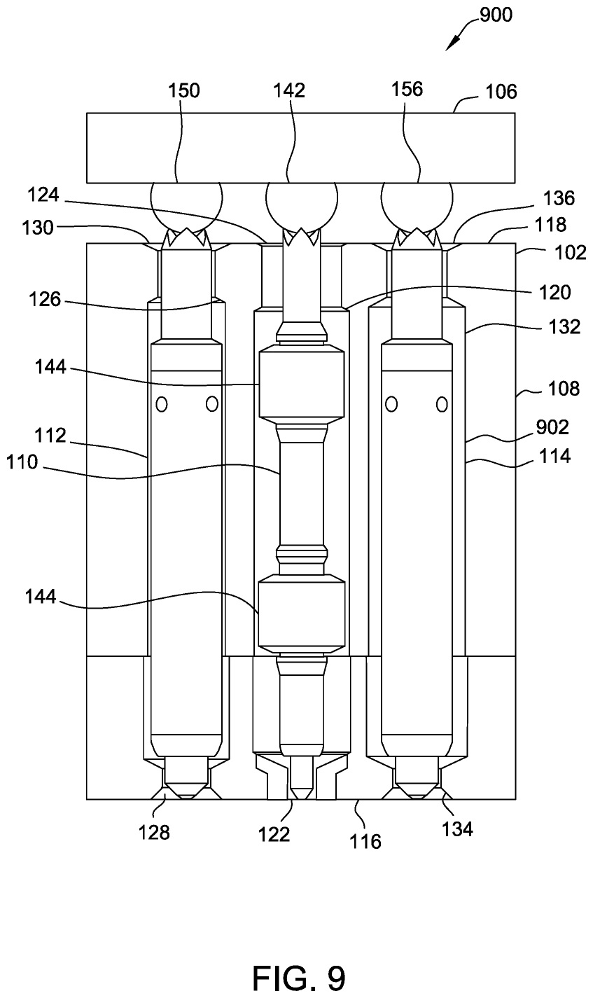

FIG. 9 is a cross sectional view of another example test assembly 900. Test assembly 900 includes test socket 102 and IC chip 106, which generally function as described with respect to FIG. 1. As shown in FIG. 9, in some embodiments, an air gap 902 is present in power cavity 132 between conductive body 108 and power probe 114. A with of air gap 902 (i.e., a radial distance between conductive body 108 and power probe 114) may be selected to achieve certain electrical characteristics.

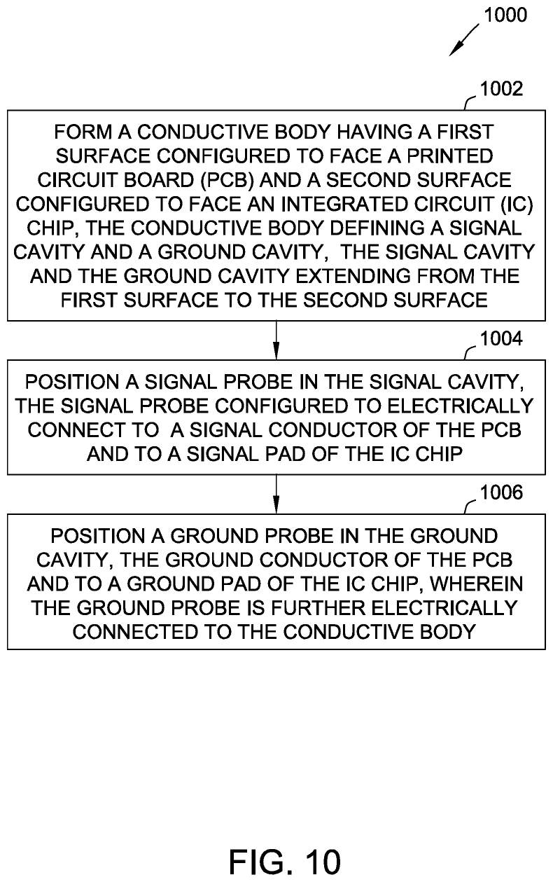

FIG. 10 is a flowchart of an exemplary method 1000 for manufacturing test socket 102. Method 1000 includes forming 1002 conductive body 108 having first surface 116 configured to face a PCB 104 and a second surface 118 configured to face IC chip 106. Conductive body 108 defines signal cavity 120 and ground cavity 126. Signal cavity 120 and ground cavity 126 extend from first surface 116 to second surface 118.

Method 1000 further includes positioning 1004 signal probe 110 in signal cavity 120. Signal probe 110 is configured to electrically connect to signal conductor 138 of PCB 104 and to signal pad 142 of IC chip 106.

Method 1000 further includes positioning 1006 ground probe 112 in ground cavity 126. Ground probe 112 is configured to electrically connect to ground conductor 148 of PCB 104 and to ground pad 150 of IC chip 106. Ground probe 112 is further electrically connected to conductive body 108.

In some embodiments, method 1000 further includes positioning insulation layer 202 on first surface 116. In some such embodiments, conductive body 108 and insulation layer 202 define recess 204 at first ground opening 128.

In certain embodiments, method 1000 further includes positioning conductive contact 402 on first surface 116. Conductive contact 302 is configured to contact ground conductor 148 of PCB 104 to electrically connect conductive body 108 to ground conductor 148. In some such embodiments, conductive contact 302 is disposed at first ground opening 128. In certain such embodiments, conductive contact 302 extends from first surface 116.

In some embodiments, method 1000 further includes positioning conductive member 402 on ground probe 112. Conductive member 402 is configured to contact conductive body 108 to electrically connect ground probe 112 to conductive body 108. In some such embodiments, conductive member 402 includes elastomer. In certain such embodiments, conductive member 402 includes a ring positioned around at least a portion of a circumference of an outside surface of ground probe 112.

In certain embodiments, method 1000 further includes forming, in conductive body 108, signal counterbore 146 at second signal opening 124 and a ground counterbore 152 at a second ground opening 130, wherein signal counterbore 146 is configured to at least partially receive signal pad 142 of IC chip 106 without contacting the signal pad 142, and wherein ground counterbore 152 is configured to at least partially receive ground pad 150 of IC chip 106.

In some embodiments, method 1000 further includes forming a plurality of conductive shield needles 702 extending from first surface 116. Conductive shield needles 702 are configured to contact ground conductor 148 to form an electrical connection between conductive body 108 and ground conductor 148. In some such embodiments, at least some conductive shield needles 702 are disposed adjacent to first signal opening 122.

In certain embodiments, method 1000 further includes positioning power probe 114 in power cavity 132 defined by conductive housing 108. Power probe 114 is configured to electrically connect to power conductor 154 of PCB 104 and to power pad 156 of IC chip 106. In some such embodiments, air gap 902 is defined in power cavity 132 radially between conductive body 108 and power probe 114.

Example embodiments of methods and systems for coaxial test socket and PCB interfaces are described above in detail. The methods and systems are not limited to the specific embodiments described herein, but rather, components of systems and/or steps of the methods may be used independently and separately from other components and/or steps described herein. Accordingly, the example embodiments can be implemented and used in connection with many other applications not specifically described herein.

Technical effects of the systems and methods described herein include at least one of: (a) improved signal integrity for a coaxial test socket by improving electrical coupling between a conductive body of the test socket and an electrical ground; and (b) increased data transfer rates for a coaxial test socket by improving electrical coupling between a conductive body of the test socket and an electrical ground.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose various embodiments, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A test socket for coupling an integrated circuit (IC) chip to a printed circuit board (PCB), said test socket comprising:
a conductive body having a first surface configured to face the PCB and a second surface configured to face the IC chip, said conductive body defining a signal cavity and a ground cavity, the signal cavity and the ground cavity extending from the first surface 5 to the second surface;
a signal probe disposed in the signal cavity, said signal probe configured to electrically connect to a signal conductor of the PCB and to a signal pad of the IC chip; and
a ground probe disposed in the ground cavity, said ground probe configured to electrically connect to a ground conductor of the PCB and to a ground pad of the IC chip, wherein said ground probe is further electrically connected to said conductive body.

2. The test socket of claim 1, further comprising an insulation layer disposed on the first surface.

3. The test socket of claim 2, wherein said conductive body and said insulation layer define a recess at an opening of the ground cavity to the first surface.

4. The test socket of claim 1, further comprising a conductive contact disposed on the first surface and configured to contact the ground conductor of the PCB to electrically connect said conductive body to the ground conductor.

5. The test socket of claim 4, wherein said conductive contact is disposed at an opening of the ground cavity to the first surface.

6. The test socket of claim 4, wherein said conductive contact extends from the first surface.

7. The test socket of claim 1, further comprising a conductive member disposed on said ground probe, said conductive member configured to contact said conductive body to electrically connect said ground probe to said conductive body.

8. The test socket of claim 7, wherein said conductive member comprises elastomer.

9. The test socket of claim 7, wherein said conductive member comprises a ring positioned around at least a portion of a circumference of an outside surface of said ground probe.

10. The test socket of claim 1, wherein said conductive body further defines a signal counterbore disposed at a first opening of the signal cavity at the second surface and a ground counterbore disposed at a second opening of the ground cavity at the second surface, wherein the signal counterbore is configured to at least partially receive the signal pad of the IC chip without contacting the signal pad, and wherein the ground counterbore is configured to at least partially receive the ground pad of the IC chip.

11. The test socket of claim 1, further comprising a plurality of conductive shield needles extending from the first surface, said conductive shield needles configured to contact said ground conductor to form an electrical connection between said conductive body and the ground conductor.

12. The test socket of claim 11, wherein at least some of said plurality of conductive shield needles are disposed adjacent to an opening of the signal cavity at the first surface.

13. The test socket of claim 1, further comprising a power probe configured to electrically connect to a power conductor of the PCB and to a power pad of the IC chip, said power probe disposed in a power cavity defined by said conductive body.

14. The test socket of claim 13, wherein an air gap is defined in the power cavity radially between said conductive body and said power probe.

15. A method for manufacturing a test socket, said method comprising:
forming a conductive body having a first surface configured to face a printed circuit board (PCB) and a second surface configured to face an integrated circuit (IC) chip, the conductive body defining a signal cavity and a ground cavity, the signal cavity and the ground cavity extending from the first surface to the second surface;
positioning a signal probe in the signal cavity, the signal probe configured to electrically connect to a signal conductor of the PCB and to a signal pad of the IC chip; and
positioning a ground probe in the ground cavity, the ground probe configured to electrically connect to a ground conductor of the PCB and to a ground pad of the IC chip, wherein the ground probe is further electrically connected to the conductive body.

16. The method of claim 15, further comprising positioning an insulation layer on the first surface, wherein the conductive body and the insulation layer define a recess at an opening of the ground cavity to the first surface.

17. The method of claim 15, further comprising positioning a conductive contact on the first surface, the conductive contact configured to contact the ground conductor of the PCB to electrically connect the conductive body to the ground conductor.

18. The method of claim 15, further comprising positioning a conductive member on the ground probe, the conductive member configured to contact the conductive body to electrically connect the ground probe to the conductive body.

19. The method of claim 15, further comprising positioning a power probe in a power cavity defined by the conductive body, the power probe configured to electrically connect to a power conductor of the PCB and to a power pad of the IC chip.

20. An integrated circuit (IC) chip testing assembly comprising:
a printed circuit board (PCB) comprising a signal conductor and a ground conductor;
an IC chip comprising a signal pad and a ground pad; and
a test socket comprising:
a conductive body having a first surface configured to face said PCB and a second surface configured to face said IC chip, said conductive body defining a signal cavity and a ground cavity, the signal cavity and the ground cavity extending from the first surface to the second surface;
a signal probe disposed in the signal cavity, said signal probe configured to electrically connect to said signal conductor and to said signal pad; and
a ground probe disposed in the ground cavity, said ground probe configured to electrically connect to said ground conductor and to said ground pad, wherein said ground probe is further electrically connected to said conductive body.
